(19) United States
(12) Patent Application Publication
(10) Pub. No.: US 2023/0407460 A1
(43) Pub. Date: Dec. 21, 2023

(54) SINGLE PHASE HIGH ENTROPY INTERMETALLICS AND METHOD FOR MANUFACTURING

(71) Applicant: THE REGENTS OF THE UNIVERSITY OF CALIFORNIA, Oakland, CA (US)

(72) Inventors: Julie M. SCHOENUNG, Oakland, CA (US); Aleksandra L. VYATSKIKH, Oakland, CA (US); Alexander D. DUPUY, Oakland, CA (US); Benjamin E. MacDONALD, Oakland, CA (US); Enrique J. LAVERNIA, Oakland, CA (US); Horst HAHN, Oakland, CA (US)

(73) Assignee: THE REGENTS OF THE UNIVERSITY OF CALIFORNIA, Oakland, CA (US)

(21) Appl. No.: 18/035,397

(22) PCT Filed: Nov. 5, 2021
(86) PCT No.: PCT/US2021/058358

§ 371 Date: May 4, 2023

Related U.S. Application Data
(60) Provisional application No. 63/110,666, filed on Nov. 6, 2020.

(51) Int. Cl. C23C 14/58; H01L 21/285; C23C 14/18; C23C 14/30

(52) U.S. Cl. CPC C23C 14/5806; H01L 21/28518; C23C 14/18; C23C 14/30

(57) ABSTRACT

A method of forming a single-phase high entropy silicide includes depositing at least two metal layers onto a silicon substrate to form a multilayer film; and heat treating the multilayer film to promote interdiffusion of the metal layer and the silicon substrate to form a single-phase silicide material.

### CROSS-REFERENCE TO RELATED PATENT APPLICATIONS

This application claims the benefit of priority to U.S. Provisional Patent Application No. 63/110,666, filed Nov. 6, 2020, which is incorporated herein by reference in its entirety.

### TECHNICAL FIELD

The present technology relates generally to high entropy materials, high entropy ceramics, high entropy silicides, CALPHAD, and thin films. More specifically, the present technology is related to a CALPHAD-guided prediction and thin film fabrication methodology.

### BACKGROUND

The field of high entropy materials design represents a departure from conventional materials design by enabling a vast and mostly unexplored compositional space. The high entropy design concept was first introduced in high entropy alloys (HEAs), alternatively called multi-principal element alloys or complex concentrated alloys [1,2]. HEAs are generally comprised of five or more principal elements in near equiatomic (“containing equal numbers of two or more atoms”) compositions. Some HEA systems achieve a single solid solution phase with a random distribution of the constituents on a crystalline lattice, which leads to interesting properties [3]. HEA research has unlocked an immense compositional space, which was previously unexplored by conventional alloy design based on a single principal element.

The high entropy materials design concept has also been applied to other materials systems, including high entropy oxides [4], high entropy borides [5], and high entropy carbides [6], where the high configurational entropy stabilizes structures with properties unattainable by the constituent materials [7]. Recently, a new class of high entropy materials—high entropy silicides (HES)—has been demonstrated [8,9]. Development of HES is particularly exciting due to their potential applications in microelectronics, where use of silicides is common. For example, silicides are used as insulation in metal-oxide-semiconductor field-effect-transistors (MOSFETs) at the gate, source, and drain terminals [10]. To date, only two HES compositions—(MoNbTaTiW)Si₂ [9] and (MoNbTaCrW)Si₂ [8]—have been reported. Both materials were synthesized in bulk form via mechanical alloying followed by spark plasma sintering (SPS). Although these studies set out to identify compositions with a single stable silicide structure, both (MoNbTaTiW)Si₂ and (MoNbTaCrW)Si₂ exhibited multiple phases, with either oxides [9] or intermetallics [8] present, making it essential to develop a deeper understanding of phase formation and evolution in HES materials. Additionally, previous work on HES materials has only considered bulk samples, and an investigation into the viability of thin film HES is required to expand these materials into IC and device applications.

The primary challenge in probing the extensive compositional space allowed by high entropy stabilization is effective screening and validation of candidate compositions.

Accordingly, there is a need to address these and other challenges.

Relatedly, silicides are commonly used in microelectronics, for example, as insulation in metal-oxide-semiconductor field-effect-transistors (MOSFETs) at the gate, source, and drain terminals. Ongoing innovation in microelectronics and constantly increasing density of devices require introduction of novel materials with improved properties. High temperature structural silicides represent an important new class of structural materials, with significant potential applications in the range of 1200-1600° C. under oxidizing and aggressive environments. Silicides, particularly those based on MoSi₂, for example, are attractive because of their combination of high melting point, elevated temperature oxidation resistance, brittle-to-ductile transition, and electrical conductivity. Possible structural uses for silicides include their application as matrices in structural silicide composites, as reinforcements for structural ceramic matrix composites, as high temperature joining materials for structural ceramic components, and as oxidation-resistant coatings for refractory metals and carbon-based materials.

High-entropy ceramics (HECs) are gaining significant interest due to their huge compositional space, unique microstructure, and adjustable properties. Previously reported studies focus mainly on HECs which have a multi-cationic structure, while HECs with more than one anion are rarely studied. High-entropy alumino-silicides (Mo_{0.25}Nb_{0.25}Ta_{0.25}V_{0.25})(Al_{0.5}Si_{0.5})₂ (HEAS-1) with multi-cationic and -anionic structures, also fall in this category.

Recently, a new class of high entropy materials—high entropy silicides (HES)—has been demonstrated. To date, only two HES compositions—(MoNbTaTiW)Si₂ and (MoNbTaCrW)Si₂—have been reported. Both materials were synthesized in bulk form via mechanical alloying followed by spark plasma sintering (SPS). It is important to note that both (MoNbTaTiW)Si₂ and (MoNbTaCrW)Si₂ exhibited secondary oxide or intermetallic phases, making it essential to develop a deeper understanding of phase formation and evolution in HES. Our invention will also apply to other silicide compositions such as: (Ti_{0.2}Zr_{0.2}Nb_{0.2}Mo_{0.2}W_{0.2})Si₂, and also (Ti_{0.22}Zr_{0.06}Nb_{0.29}Mo_{0.22}W_{0.21})Si₂ with zirconium partially oxidized into zirconia.

High Entropy Intermetallics (HEIs) are important in structural and energy applications; to date HEIs have only been fabricated as secondary phases in other matrices, and have been shown to have unique combinations of physical and mechanical attributes.

Additionally, previous work on HES materials has only considered bulk samples, and development of thin film fabrication methods for HES is required for integrated circuit and device applications.

### SUMMARY

In one aspect, which may be combined with any other aspect or embodiment, a method of forming a single-phase high entropy silicide material is provided, the method comprises, consists essentially of, or consists of depositing at least two metal layers onto a silicon substrate to form a multilayer film and heat treating the multilayer film at a sufficient temperature to promote interdiffusion of the metal layer and the silicon substrate to form the single-phase high entropy silicide material. In some aspects, the depositing step and the heat treating step are performed sequentially or concurrently.

In another aspect, the step of depositing at least two metal layer comprises, consists essentially of, or consists of electron beam evaporating at least two metals onto the silicon substrate. In some aspects, the at least one metal comprises, consists essentially of, or consists of Mo, Cr, Ta, Nb or V. In yet another aspect, the at least two metal layers comprises, consists essentially of, or consists of, in no particular order a first layer comprising Cr, a second layer comprising Mo, and a third layer comprising Ta. In some aspects, the Cr, Mo, and Ta are deposited onto the Si substrate in an approximately equiatomic ratio. In some aspects the depositing comprises sequentially depositing the metal layers onto the silicon substrate. In some aspects, the at least two metal layers comprise, consist essentially of, or consist of, in no particular order, a first layer comprising Cr, a second layer comprising Mo, a third layer comprising Ta, a fourth layer comprising Nb, and a fifth layer comprising V.

In another aspect, the single-phase silicide material is (CrMoTa)Si₂. In some aspects, the single-phase silicide material is (CrMoTaVNb)Si₂

In yet another aspect, a method of identify a candidate single-phase high entropy silicide is provided, the method comprising, consisting essentially of, or consisting of using the CALculation of PHAse Diagrams (CALPHAD) approach to identify two candidate single-phase high entropy silicides (HES): the ternary (CrMoTa)Si₂ and the quinary (CrMoTaVNb)Si₂.

In another aspect, the method further comprises, consists essentially or, or consists of experimentally synthesizing both candidate compositions via electron beam evaporation followed by heat treatment in vacuum, so as to facilitate the solid-state reaction and formation of a single-phase.

In another aspects, both the ternary (CrMoTa)Si₂ and the quinary (CrMoTaVNb)Si₂ HES films form a single phase with a C40 hexagonal crystal structure.

In yet another aspect, a thin film high entropy silicide material is provided by using the CALculation of PHAse Diagrams (CALPHAD) approach to identify two candidate single-phase high entropy silicides (HES): the ternary (CrMoTa)Si₂ and the quinary (CrMoTaVNb)Si₂ and experimentally synthesizing both candidate compositions via electron beam evaporation followed by heat treatment in vacuum, so as to facilitate the solid-state reaction and formation of a single-phase.

In another aspect, a method of forming a single-phase high entropy comprises, consists essentially of, or consists of depositing at least one metal layer onto a silicon substrate to form a multilayer film and heat treating the multilayer film to promote interdiffusion of the metal layer and the silicon substrate to form a single-phase silicide material. In some aspects, the depositing step and the heat treating step are performed sequentially or concurrently.

In another aspects the step of depositing at least one metal layer comprises, consists essentially of, or consists of electron beam evaporating at least one metal onto the silicon substrate. In some aspects, the at least one metal comprises, consists essentially of, or consists of Mo, Cr, Ta, Nb or V,

In yet another aspect, the depositing step comprises, consists essentially of, or consists of sequentially depositing a plurality of metal layers onto the silicon substrate. In some aspects, the metal layers comprises, consists essentially of, or consist of Cr, Mo, and Ta. In some aspects, Cr, Mo, and Ta are deposited onto the Si substrate with an equiatomic ratio.

### BRIEF DESCRIPTION OF THE DRAWINGS

These and other aspects and features of the present embodiments will become apparent to those ordinarily skilled in the art upon review of the following description of specific embodiments in conjunction with the accompanying figures.

FIG. 1A is a schematic of the electron beam evaporation process used to fabricate multilayer films. FIG. 1B is a schematic of multilayer films heat treated at temperature T_{HT} in a vacuum furnace to facilitate a solid-state transformation to a single-phase silicide material following the deposition.

FIG. 2A is a calculated equilibrium step diagram of the ternary (CrMoTa)Si₂ HES, showing the equilibrium phases over a range of temperatures (left). A schematic unit cell of ternary (CrMoTa)Si₂ HES with a C40 hexagonal crystal structure, showing equal probability of site occupation by Cr, Mo and Ta atoms on the metal cation sublattice as predicted by CALPHAD (right). FIG. 2B is a calculated equilibrium step diagram for the quinary (CrMoTaVNb)Si₂ HES, showing the equilibrium phases over a range of temperatures (left). A schematic unit cell of the quinary (CrMoTaVNb)Si₂ HES with a C40 hexagonal crystal structure, showing equal probability of site occupation by Cr, Mo, Ta, V and Nb atoms on the metal sublattice as predicted by CALPHAD (right).

FIG. 3A illustrates grazing incidence X-ray diffraction (GIXRD) patterns collected from the as-deposited multilayer Cr, Mo and Ta film reveal a broad peak attributed to the (110) planes of the elemental BCC Cr, Mo and Ta (indicated with dashed lines). FIG. 3B illustrates GIXRD patterns collected from the ternary (CrMoTa)Si₂ HES thin film after heat treatment at 900° C. for 30 min reveal a single-phase material with a C40 hexagonal crystal structure with some surface oxidation. FIG. 3C is a SEM micrograph of a fracture cross-section of the ternary (CrMoTa)Si₂ silicide thin film on Si substrate. FIG. 3D is a top-down SEM micrograph showing the nanocrystalline ternary (CrMoTa)Si₂ HES thin film.

FIG. 4A illustrates grazing incidence X-ray diffraction (GIXRD) patterns collected from the as-deposited multilayer film reveal peaks attributed to the (110) planes of the elemental Cr, Mo, Ta, V, Nb (indicated with dashed lines). FIG. 4B illustrates GIXRD patterns collected from the reacted quinary (CrMoTaVNb)Si₂ HES film after heat treatment at 900° C. for 30 min demonstrate a single-phase material with a C40 hexagonal crystal structure. FIG. 4C is a cross-sectional SEM micrograph showing the reacted quinary (CrMoTaVNb)Si₂HES film on a Si substrate. FIG. 4D is a top-down SEM micrograph showing the reacted quinary (CrMoTaVNb)Si₂ HES thin film.

FIG. 5A illustrates calculated equilibrium step diagrams of recently reported high entropy silicide materials suggested by Liu et al. Materials suggested by Liu et al. [1] exhibit secondary phase formation, as compared to the material suggested in this work. FIG. 5B illustrates calculated equilibrium step diagrams of recently reported high entropy silicide materials suggested by Gild et al. [2] exhibit secondary phase formation, as compared to the material suggested in this work.

FIG. 6 is a cross-sectional SEM micrograph of the as-deposited Cr, Mo, Ta multilayer film.

FIG. 7 illustrates heat treatment optimization on the ternary (CrMoTa)Si₂ high entropy material. GIXRD patterns collected at ω=0.5° indicate that heat treatment at 900° C. for 30 min yields a single-phase medium entropy silicide with a C40 crystal structure.

FIG. 8 is a cross-sectional SEM micrograph of an as-deposited Cr, Mo, Ta, V and Nb multilayer film.

FIG. 9 is EDS mapping of the reacted quinary (CrMoTaVNb)Si₂ high entropy silicide. a) A secondary electron image, b) EDS spectrum. FIGS. C-H are elemental maps.

### DETAILED DESCRIPTION

The present embodiments will now be described in detail with reference to the drawings, which are provided as illustrative examples of the embodiments so as to enable those skilled in the art to practice the embodiments and alternatives apparent to those skilled in the art. Notably, the figures and examples below are not meant to limit the scope of the present embodiments to a single embodiment, but other embodiments are possible by way of interchange of some or all of the described or illustrated elements. Moreover, where certain elements of the present embodiments can be partially or fully implemented using known components, only those portions of such known components that are necessary for an understanding of the present embodiments will be described, and detailed descriptions of other portions of such known components will be omitted so as not to obscure the present embodiments. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the present disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present embodiments encompass present and future known equivalents to the known components referred to herein by way of illustration.

As utilized herein with respect to numerical ranges, the terms “approximately,” “about,” “substantially,” and similar terms will be understood by persons of ordinary skill in the art and will vary to some extent depending upon the context in which it is used. If there are uses of the terms that are not clear to persons of ordinary skill in the art, given the context in which it is used, the terms will be plus or minus 10% of the disclosed values. When “approximately,” “about,” “substantially,” and similar terms are applied to a structural feature (e.g., to describe its shape, size, orientation, direction, etc.), these terms are meant to cover minor variations in structure that may result from, for example, the manufacturing or assembly process and are intended to have a broad meaning in harmony with the common and accepted usage by those of ordinary skill in the art to which the subject matter pertains. Accordingly, these terms should be interpreted as indicating that insubstantial or inconsequential modifications or alterations of the subject matter described and claimed are considered to be within the scope of the disclosure as recited in the appended claims.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

It has now been found that, among other things, computational thermodynamics techniques, such as the CALculation of PHAse Diagrams (CALPHAD) approach, can be used to predict the phase stability of a given composition and reveal promising candidate compositions. Advancements in the underlying thermodynamic databases used with the CALPHAD approach have made prediction of the phase formation in multiple high entropy silicides (HEA) materials more reliable [11-13], and have the extension of the CALPHAD approach directly to the development of complex HES compositions with targeted phase stability.

In this disclosure, the CALPHAD approach is used to identify two single-phase HES materials: the ternary (CrMoTa)Si₂ and quinary (CrMoTaVNb)Si₂. Such single-phase HES materials may be prepared using thin film formation through electron beam evaporation of the metal constituents onto a Si substrate, followed by a heat treatment to induce a solid-state reaction between the Si substrate, and the metal constituents. In addition to electron beam evaporation, some embodiments may utilize pulsed laser deposition or sputtering techniques to prepare the metal constituents onto the Si substrate. Furthermore, the preparation of the single-phase HES materials may include co-deposition of multiple elements simultaneously using a pre-alloyed target or multiple targets. In yet further embodiments, the preparation of single-phase HES materials may include the deposition of Si rather than diffusion from the substrate.

Finally, the present Applicants use grazing incidence X-ray diffraction (GIXRD) depth profiling and scanning electron microscopy (SEM) to evaluate the phase composition and microstructure of the ternary (CrMoTa)Si₂ and quinary (CrMoTaVNb)Si₂ HES thin films. Both (CrMoTa)Si₂ and (CrMoTaVNb)Si₂ exhibit a single-phase state with a C40 hexagonal crystal structure, which is consistent with the CALPHAD predictions.

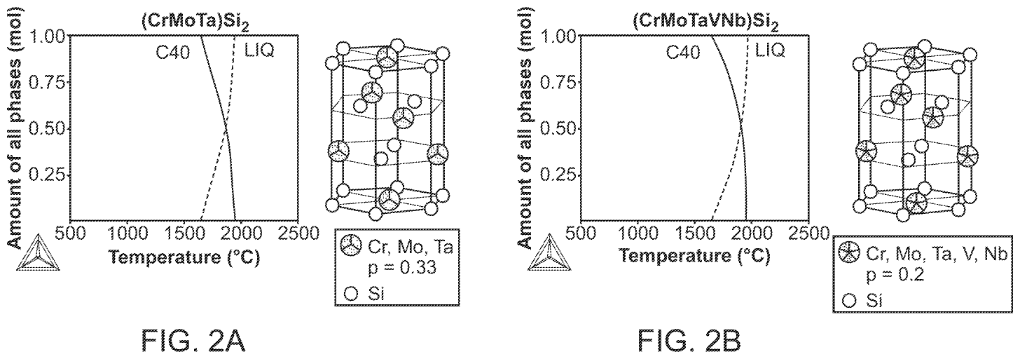

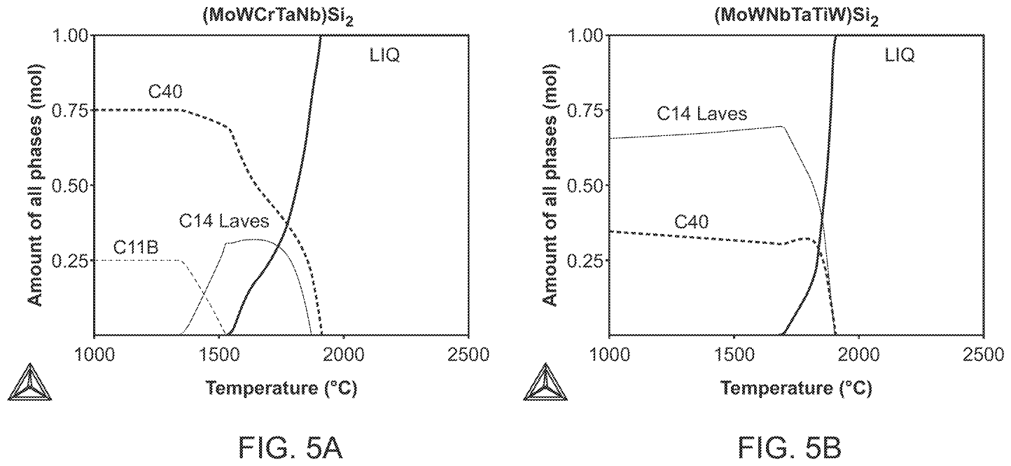

The CALPHAD approach is employed to identify candidate silicide compositions that are predicted to form a single phase with a C40 hexagonal crystal structure. The CALPHAD approach involves thermodynamic calculation of the free energy of the system. The calculations of the free energy of the system are used to evaluate the phase formation that may yield the lowest free energy at a given temperature. From these calculations, a prediction of the thermodynamically stable phase of the material composition is identified. As seen in FIGS. 2A-B and 5A-B illustrating the equilibrium step diagrams, the the ternary (CrMoTa)Si₂ and quinary (CrMoTaVNb)Si₂ HES compositions exhibit a single-phase in the solid state, while other compositions may yield multiple phases in the solid state (See FIG. 5).

ThermoCalc Software equipped with the TCHEA3 HEA thermodynamic database was used for the CALPHAD calculations. The TCHEA3 database produced by ThermoCalc contains the necessary models for silicide structures and constituent elements to assess the phase stability in refractory metal silicide systems [14].

### Methods for Fabrication of Silicide Thin Films

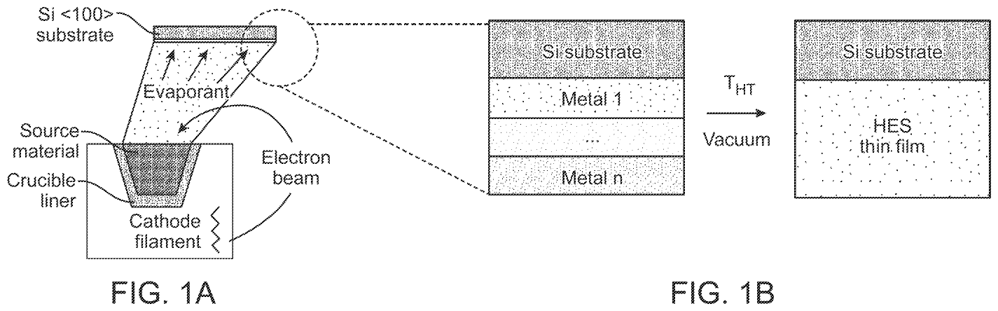

Referring to FIGS. 1A and 1B, the silicide thin films are fabricated via a two-step process. First, metal layers (Cr, Mo and Ta for (CrMoTa)Si₂; Ta, V, Nb, Cr, and Mo for (CrMoTaVNb)Si₂) are sequentially deposited onto a Silicon substrate (FIG. 1A). In some embodiments, the order in which the metals layers are deposited may vary and may depend upon the particular metals being deposited. In some embodiments, the metals may be deposited in an order in which metals with a higher propensity for oxidation are deposited first and on the bottom, with the metals having the lowest propensity for oxidation deposited last and on the top of the film. Including the metals with the lowest propensity to oxidize may minimize the contamination of the end product. However, this ordering does not necessarily enable the formation of the single phase silicide film and different ordering of the metal layers are possible depending upon the desired features of the single-phase high entropy silicide material. Furthermore, co-deposition of various metal layers simultaneously is a demonstrably viable route as well in the formation of single-phase materials.

The thicknesses of the individual metal layers (Table 2) may be selected to obtain the desired silicide composition after full reaction with Si. The as-deposited multilayer films of metals are then heat treated to facilitate the interdiffusion of the metals and Si and further enhance the solid-state transformation to a single-phase silicide material (FIG. 1B).

Metal pellets of V, Nb, Cr, Ta and Mo, with >99.7% purity (Kurt J. Lesker Company, Jefferson Hills, PA, USA), were used for electron beam evaporation. Thin films of each of these metals were deposited in an electron beam evaporator (Angstrom Engineering EvoVac Glovebox) with the pressure maintained at <2.9·10⁻⁷ Torr during the deposition. The evaporation parameters, including power and deposition rate for each layer, are summarized in Table 2. The deposition rates were measured with a quartz crystal monitor (QCM). Films were deposited onto undoped Si <100> wafers (University Wafer, South Boston, MA, USA). Heat treatment was performed using a vacuum furnace (Centrorr M60) under a pressure of <1×10⁻⁵ Torr. During heat treatment, samples were placed inside a graphite crucible and heated to 800-900° C. for 30-60 min with a heating rate of 10° C./min. The furnace was turned off at the end of the heat treatment and allowed to cool naturally.

GIXRD diffraction patterns were collected with a diffractometer equipped with a 2.2 kW Cu-Kα X-ray source with λ=1.54187 Å (Rigaku Smartlab). The diffractometer was configured in parallel beam geometry and ω-2θ mode, with the incidence angle ω set to 0.2°, 0.4°, 0.55°, 0.6°, 0.8° and 1.2° to facilitate depth profiling. The patterns were collected in the 2θ range of 20-50° with 0.05° step and at a scan speed of 0.65°/s. PDF cards No. 00-004-0809, 00-006-0694, 00-004-0788, 00-034-0370, 00-022-1058 were used to identify the (110) peak position for Mo, Cr, Ta, Nb and V, respectively. Lattice parameters for the (CrMoTa)Si₂ and (CrMoTaVNb)Si₂ thin film samples were determined by performing full-pattern Rietveld refinement using the GSAS-II software package [15].

Secondary electron micrographs were obtained with a scanning electron microscope (SEM, FEI Magellan 400) equipped with a through-the-lens (TLD) detector operated in immersion mode. Cross-sectional imaging was performed by fracturing the samples, and film thicknesses were measured from the fracture cross-section micrographs using ImageJ [16]. Average grain sizes were measured from the top-down SEM micrographs according to the Abrams three-circle procedure described in ASTM E112-13 [17]. Energy-dispersive X-ray spectroscopy (EDS) was performed with a silicon drift detector (Oxford Instruments X-Max) at an accelerating voltage of 5 kV and a beam current of 0.2 nA.

### Identification of Single-Phase Silicide Compositions

Candidate single-phase silicide compositions are identified by conducting a systematic evaluation of phase stability using the CALPHAD approach. Equilibrium step diagrams produced by the CALPHAD approach, which show the relative amount of each stable phase calculated as a function of temperature, are used to assess a composition's propensity to form a single-phase state. By comparing the equilibrium step diagrams for a variety of silicide compositions containing three or more refractory metal elements in equiatomic ratios, i.e., (M₁, M₂, M₃, . . . , Mₓ)Si₂, two candidate single-phase HES compositions were identified: the ternary (CrMoTa)Si₂ and the quinary (CrMoTaVNb)Si₂. Both the ternary (CrMoTa)Si₂ (FIG. 2A) and the quinary (CrMoTaVNb)Si₂ (FIG. 2B) are predicted to exhibit a single phase with a C40 hexagonal crystal structure.

Stability of the high entropy C40 phase predicted by CALPHAD is in agreement with previous studies on phase stability in MoSi₂-based ternary silicides, where the presence of the C40 phase was shown to be ubiquitous [18]. Moreover, the (CrMoTa)Si₂ and (CrMoTaVNb)Si₂ compositions are unique in their predicted single C40 phase formation as compared to the previously reported HES materials. FIG. 5 illustrates the equilibrium step diagrams for the (MoNbTaTiW)Si₂ [9] and (MoNbTaCrW)Si₂ [8], which are predicted to exhibit multiple phases at equilibrium, confirming previously reported observations of secondary phases. FIG. 2 illustrates the CALPHAD prediction of the two candidate silicides.

### Methods of Manufacturing Single-Phase High Entropy Silicide Materials

In one aspect, the present disclosure relates to a novel single-phase high entropy silicide material (CrMoTaVNb)Si₂ and a manufacturing method to produce this material as a thin film. The proposed method is applicable to other HES and HEC compositions, as described above. In a more general sense, the embodiments will also apply to all High Entropy Intermetallic (HEI) single-phase materials. The term “high entropy” may be used to describe materials having of multiple constituents, wherein the constituents include near equiatomic ratios within a composition.

The manufacturing method includes two steps: (1) thin film deposition (e.g., physical vapor deposition) and (2) heat treatment. These two steps can be performed either concurrently or sequentially. This manufacturing method is compatible with industry-standard microelectronics processing techniques (e.g., the salicide process). It is expected that the (CrMoTaVNb)Si₂ material can be used in microelectronics. For example, in contrast to previously reported high entropy silicides, this (CrMoTaVNb)Si₂ material is single-phase, which is desirable for applications in microelectronics. Additionally, this manufacturing method based on physical vapor deposition is compatible with microelectronics processing, in contrast to mechanical alloying and spark plasma sintering used in prior art. Still further, this manufacturing process is facile, and does not require additional instrumentation compared to mechanical alloying and spark plasma sintering reported in prior art.

In some aspects, the field of high entropy materials provides a vast, multicomponent compositional space, where scientifically interesting and technologically important materials with novel properties can be identified. Recently, the design methodologies that are traditionally used for high entropy alloys have been extended to silicide materials, which are particularly promising due to their potential applications in microelectronics. In aspects, the CALculation of PHAse Diagrams (CALPHAD) approach is used to identify two candidate single-phase high entropy silicides (HES): the ternary (CrMoTa)Si₂ and the quinary (CrMoTaVNb)Si₂. Both candidate compositions are experimentally synthesized via electron beam evaporation followed by heat treatment in vacuum, which facilitates the solid-state reaction and formation of a single-phase. Both the ternary (CrMoTa)Si₂ and the quinary (CrMoTaVNb)Si₂ HES films formed a single phase with a C40 hexagonal crystal structure, validating the CALPHAD phase formation predictions. This disclosure reports the first experimental realization of a thin film, high entropy, silicide material.

The present invention, thus generally described, will be understood more readily by reference to the following examples, which are provided by way of illustration and are not intended to be limiting of the present invention.

### EXAMPLES

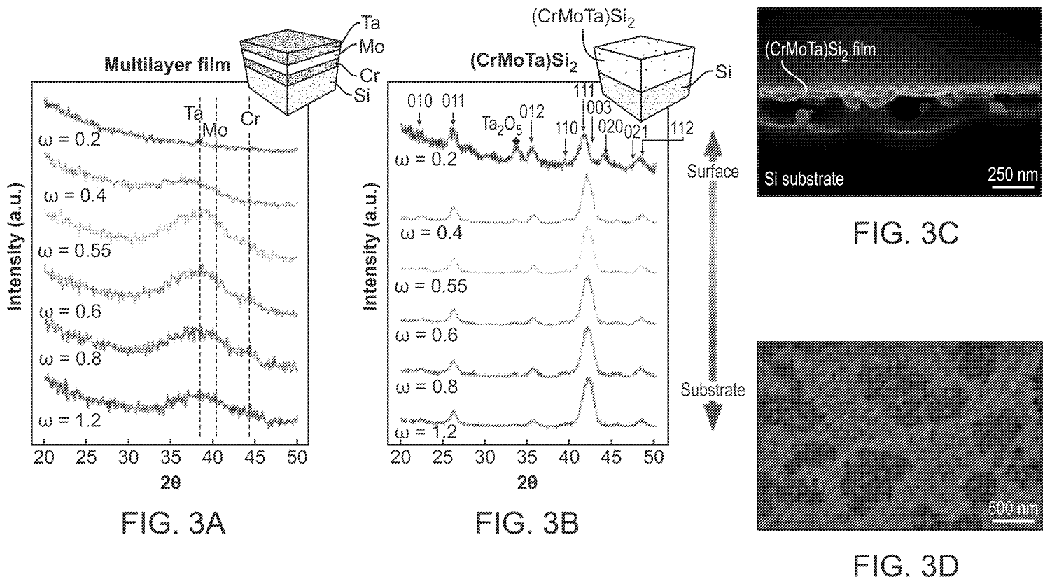

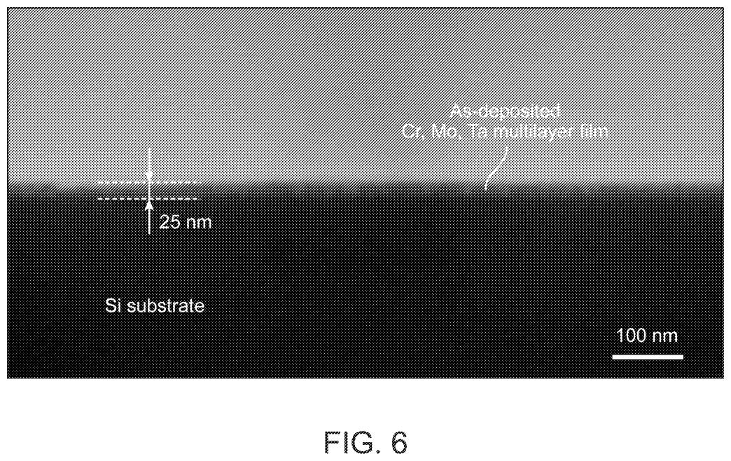

Example 1. Fabrication of Ternary Silicide Compositions. To fabricate the ternary (CrMoTa)Si₂ silicide, layers of Cr, Mo, and Ta are sequentially deposited onto a Si substrate with an equiatomic ratio of each constituent metal. The total thickness of the as-deposited ternary multilayer film was about 25 nm, as determined by cross-sectional SEM micrography (FIG. 6). GIXRD patterns for the as-deposited ternary multilayer thin film exhibit a broad peak centered around ˜37° (FIG. 3A), which is indexed to the (110) peak of the body-centered cubic (BCC) structures of Cr, Mo, and Ta.

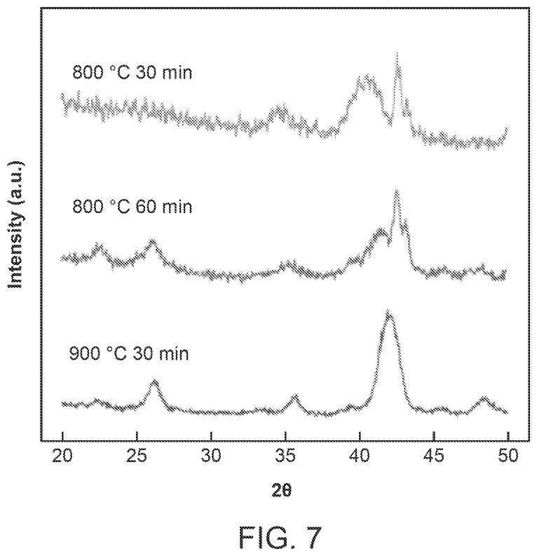

To determine the appropriate heat treatment conditions for fully reacting the multilayer film, several discrete temperature/time combinations are evaluated between 800-900° C. and 30-60 min, and corresponding GIXRD patterns collected from the heat-treated samples are shown in FIG. 7. It was found that heat treating the multilayer structure at 900° C. for 30 min yielded a single-phase material with a C40 hexagonal crystal structure with no extraneous peaks, indicating a complete transformation of the multilayer structure to the single (CrMoTa)Si₂ phase. Formation of a single phase with a C40 hexagonal crystal structure in (CrMoTa)Si₂ is not surprising given that the constituent silicides CrSi₂ and MoSi₂ both stabilize in a hexagonal C40 structure [19], and the C40 β-MoSi₂ phase is metastable relative to the tetragonal α-MoSi₂ C11_{b} phase [20]. Additionally, (MoTa)Si₂ stabilizes a single C40 phase at ˜0.45-1.0 mole fractions of TaSi₂, and (CrMo)Si₂ stabilizes a single C40 phase at ˜0.65-1.0 mole fractions of CrSi₂ [18]. The (CrMoTa)Si₂ ternary has also been shown to form a single C40 phase at approximately equiatomic compositions [18].

GIXRD depth profiling is used to confirm the phase uniformity of the reacted ternary (CrMoTa)Si₂ silicide thin film after heat treatment at 900° C. for 30 min (FIG. 3B). All GIXRD patterns are indexed to a hexagonal C40 crystal structure, confirming that the solid-state reaction yielded a uniform single-phase state throughout the thickness of the film. A single extraneous peak observed in the ω=0.2° pattern at ˜33.6° may correspond to surface oxidation of the Ta layer and formation of Ta₂O₅ [21]. The oxidation may be attributed to the fact that the Ta layer was deposited last and, therefore, exposed to air during sample manipulation. Observation of the single C40 phase in the (CrMoTa)Si₂ silicide film confirms our CALPHAD predictions (FIG. 2A).

An SEM micrograph of the fracture cross-section of the reacted ternary (CrMoTa)Si₂ silicide film is presented in FIG. 3C. The reacted ternary (CrMoTa)Si₂ film is ˜42 nm in thickness, which constituted a ˜70% increase in thickness compared to the as-deposited multilayer film. The growth of the film after heat treatment is indicative of Si incorporation into the metal film during the heat treatment. Voids are observed distributed uniformly along the interface between the ternary (CrMoTa)Si₂ HES film and the Si substrate. The void formation is attributed to the Kirkendall effect, which occurs due to the majority atoms (Si) being more mobile than the minority atoms (Cr, Mo and Ta) [22].

The thickness of the reacted film is in line with the ˜37 nm thickness predicted from the theoretical density of 6.97 g/cm³. Theoretical density was calculated based on the lattice parameters obtained from full-pattern refinement (Table 1) for the C40 hexagonal crystal structure with equal probability of site occupation by Cr, Mo and Ta atoms assuming ideal stoichiometry.

The film exhibits a uniform microstructure (FIG. 3D), with an average grain size of 40±3 nm. Additionally, no obvious cracks or pores are observed on the surface of the film. The Kirkendall voids under the film appear as dark regions in the top-down micrograph due to fewer emitted secondary electrons (FIG. 3D).

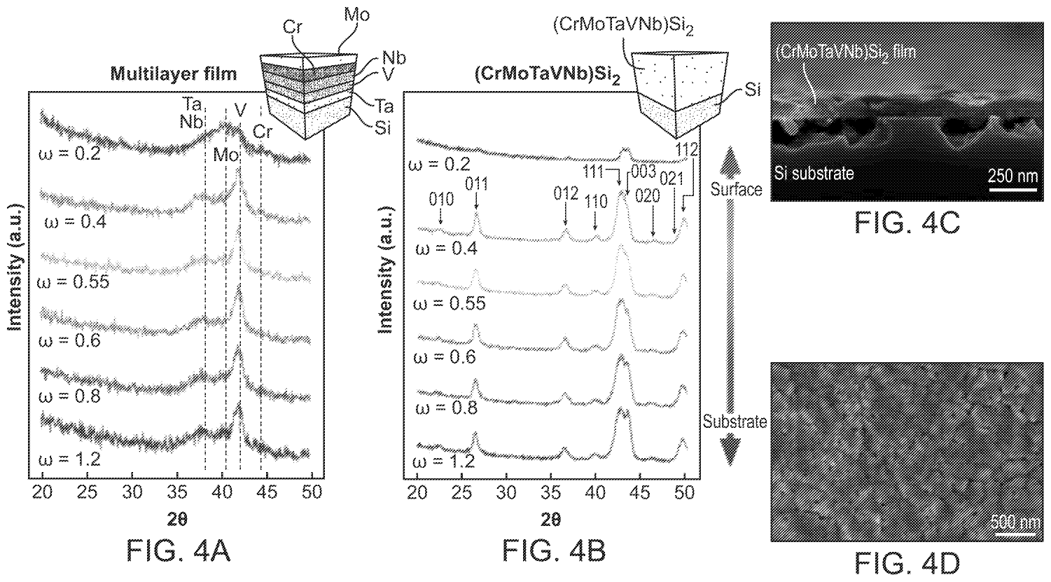

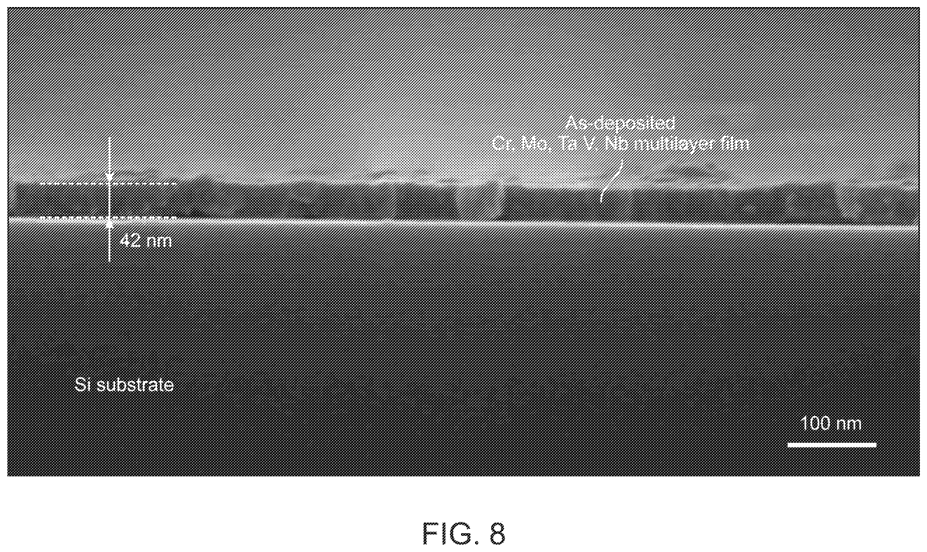

Example 2: Fabrication of Quinary Silicide Compositions. The same approach developed for the ternary (CrMoTa)Si₂ HES film may be utilized to fabricate a quinary (CrMoTaVNb)Si₂ HES. To avoid the surface oxidation observed in the ternary (CrMoTa)Si₂ film (FIG. 3B at ω=0.2°), the deposition order of the constituent metals was revised. The five metals are deposited according to their room temperature Gibbs free energy of oxide formation (ΔG_{f}): the Ta layer was deposited first (ΔG_{f}=−1911 kJ/mol), followed by V (ΔG_{f}=−1803 kJ/mol), Nb (ΔG_{f}=−1766 kJ/mol), Cr (ΔG_{f}=−1053 kJ/mol), and, finally, Mo (ΔG_{f}=−668 kJ/mol) [23]. The metals are deposited in equiatomic ratios, and the thickness of the as-deposited multilayer film, as determined from an SEM micrograph of the fracture cross-section, is ˜42 nm (FIG. 8). GIXRD patterns obtained from the as-deposited multilayer thin film (FIG. 4A) exhibit a broad peak at ˜38°, which is indexed to the (110) peaks of Ta, Nb and Mo. Another peak present at ˜42° is attributed to the (110) lattice planes of elemental V.

Following the procedure previously established for the ternary (CrMoTa)Si₂ film, the as-deposited Cr, Mo, Ta, V, Nb multilayer film is then heat treated at 900° C. for 30 minutes, and its phase composition was evaluated through GIXRD (FIG. 4B). The diffraction patterns exhibited peaks indexed to the C40 hexagonal crystal structure throughout the entire thickness of the film, confirming the CALPHAD predictions of phase formation in (CrMoTaVNb)Si₂. Similar to the ternary (CrMoTa)Si₂, formation of a single phase with a C40 hexagonal crystal structure is expected in (CrMoTaVNb)Si₂ due to the prevalence of the C40 crystal structure in the constituent silicides CrSi₂, MoSi₂, TaSi₂, VSi₂ and NbSi₂ [18]. Formation of a single phase with a C40 hexagonal crystal structure in the (CrMoTa)Si₂ ternary silicide discussed above also supports this finding. No secondary phases were evident from the diffraction patterns, indicating a complete reaction to the high entropy (CrMoTaVNb)Si₂ phase. In contrast to the ternary (CrMoTa)Si₂ silicide (FIG. 3B), no surface oxidation was observed in the (CrMoTaVNb)Si₂film.

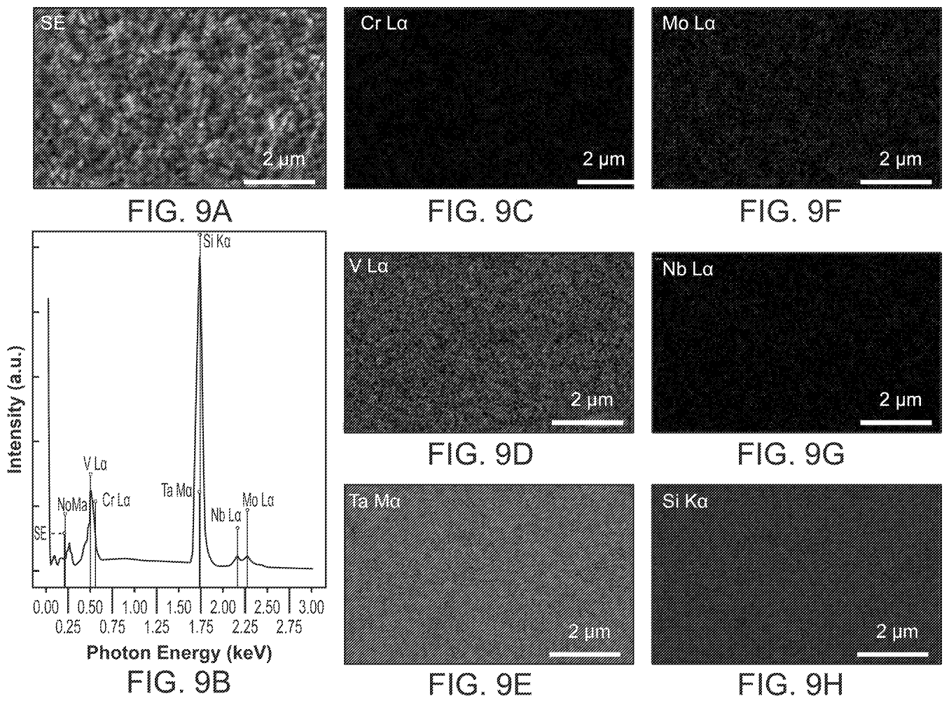

A cross-sectional SEM micrograph of the reacted quinary (CrMoTaVNb)Si₂ HES film (FIG. 4C) revealed that the film grew to ˜101 nm in thickness after heat treatment. The ˜143% increase in thickness is attributed to the incorporation of Si atoms from the substrate during the reaction process. The thickness of the reacted film is ˜21% larger than the ˜80 nm thickness predicted from the theoretical density of 6.25 g/cm³. The deviation from the predicted thickness can be attributed to film porosity, as well as potential errors in thickness measurements of metal layers during electron beam evaporation. Kirkendall voids were observed at the interface between the film and the substrate, indicating a similar reaction process to the ternary (CrMoTa)Si₂ sample. However, these voids were not observed from a top-down view due to the thickness of the film (FIG. 4D). A nonuniform grain size distribution was observed in the quinary (CrMoTaVNb)Si₂HES film, with grains ranging from ˜145 nm to ˜280 nm and an average grain size of 198±13 nm. The increase in grain size compared to the ternary film can be attributed to abnormal grain growth associated with the more complex solid-state reaction process required to form the quinary sample. A homogenous elemental distribution was confirmed through EDS mapping (FIG. 9) of the reacted quinary (CrMoTaVNb)Si₂ film, which revealed no large-scale segregation nor secondary phases.

Quantitative analysis using Rietveld refinement was performed on the diffraction patterns obtained from both silicide materials at ω=0.55°. The measured lattice parameters a and c were compared to the lattice parameters calculated from Vegard's law [24] (Table 1). The difference between the measured and the calculated lattice parameters is <0.35% for a and <1.5% for c. The close correspondence of the measured and calculated lattice parameters indicates that both the ternary and quinary silicide materials fabricated in this work follow the ideal rule of mixing and have solid-solution structures. The present Applicants interpret this agreement with Vegard's law as a confirmation that all of the constituent metal elements have been incorporated on the cation sublattice of the C40 hexagonal solid-solution structure

TABLE 1
Lattice parameters of (CrMoTa)Si₂ and (CrMoTaVNb)Si₂
HES with C40 hexagonal crystal structure.

| | | | Axial | |
|---|---|---|---|---|
| | | | ratio | |
| Material | a (nm) | c (nm) | c/a | Reference |
| CrSi₂ | 0.4428 | 0.6368 | 1.438 | [19] |
| (experimental) | | | | |
| β-MoSi₂ | 0.4596 | 0.6550 | 1.425 | [19] |
| (experimental) | | | 1.373 | [19] |
| TaSi₂ | 0.4784 | 0.6570 | | |
| (experimental) | | | | |
| VSi₂ | 0.4572 | 0.6373 | 1.394 | [19] |
| (experimental) | | | | |
| NbSi₂ | 0.4797 | 0.6592 | 1.374 | [19] |
| (experimental) | | | | |
| (CrMoTa)Si₂ | 0.4618 | 0.6423 | 1.391 | This work |
| Rietveld | | | | |
| (experimental) | | | | |
| (CrMoTa)Si₂ | 0.4602 | 0.6496 | 1.411 | This work |
| Vegard's Law | | | | |
| (calculated) | | | | |
| (CrMoTaVNb)Si₂ | 0.4644 | 0.6437 | 1.386 | This work |
| Rietveld | | | | |
| (experimental) | | | | |
| (CrMoTaVNb)Si₂ | 0.4635 | 0.6491 | 1.400 | This work |
| Vegard's | | | | |
| Law (calculated) | | | | |

TABLE 2
Electron beam evaporation parameters

| | | | | | | |
|---|---|---|---|---|---|---|
| | | | | | Quartz Crystal | |
| | | Target | | | Monitor | |
| | | layer | Crucible | | (QCM) | |
| Layer | | thickness | Liner | | Deposition | Power |
| No. | Material | (nm) | Material | Ratio | Rate (Å/s) | (%) |

(CrMoTa)Si₂

| | | | | | | |
|---|---|---|---|---|---|---|
| 1 | Cr | 4.00 | Graphite | 1.15 | 0.50 | 1.7 |
| 2 | Mo | 5.21 | Graphite | 1.23 | 0.26 | 23.0 |
| 3 | Ta | 6.00 | Graphite | 1.50 | 0.51 | 19.8 |

(CrMoTaVNb)Si₂

| | | | | | | |
|---|---|---|---|---|---|---|
| 1 | Ta | 7.19 | Graphite | 1.50 | 0.15 | 20.0 |
| 2 | V | 5.63 | Tungsten | 1.13 | 0.49 | 2.8 |
| 3 | Nb | 7.19 | Fabmate | 1.42 | 0.30 | 25.3 |
| 4 | Cr | 4.80 | Graphite | 1.15 | 0.50 | 2.2 |
| 5 | Mo | 6.24 | Graphite | 1.23 | 0.60 | 10.0 |

These examples demonstrate the successful implementation of the CALPHAD approach to the design of compositionally complex high entropy silicide systems. The present Applicants identified two single-phase HES materials: the ternary (CrMoTa)Si₂ and quinary (CrMoTaVNb)Si₂.

In some embodiments, silicide materials can be fabricated via electron beam evaporation followed by a solid-state reaction facilitated by heat treatment in vacuum. As evidenced by GIXRD, both (CrMoTa)Si₂ and (CrMoTaVNb)Si₂ exhibit a single phase with a C40 hexagonal crystal structure, corroborating our CALPHAD predictions. Lattice parameters obtained from the experimental GIXRD patterns after full pattern refinement are in close alignment with lattice parameters calculated from Vegard's law, indicating incorporation of all constituent elements onto the metal sublattice of the C40 hexagonal phase.

In some embodiments, the fabrication process is compatible with industry-standard deposition processes used in microelectronics, and can therefore be implemented in device fabrication.

The thin film fabrication process is compatible with high throughput materials synthesis and characterization techniques, potentially enabling fast and facile screening of novel scientifically interesting HES materials. The disclosure exhibits a rationally selected, experimentally synthesized thin film single-phase high entropy silicide.

### REFERENCES

[1] B. Cantor, I. T. H. Chang, P. Knight, A. J. B. Vincent, Microstructural development in equiatomic multicomponent alloys, Mater. Sci. Eng. A. 375-377 (2004) 213-218. doi:10.1016/j.msea.2003.10.257.
[2] J. W. Yeh, S. K. Chen, S. J. Lin, J. Y. Gan, T. S. Chin, T. T. Shun, C. H. Tsau, S. Y. Chang, Nanostructured high-entropy alloys with multiple principal elements: Novel alloy design concepts and outcomes, Adv. Eng. Mater. 6 (2004) 299-303. doi:10.1002/adem.200300567.
[3] D. B. Miracle, O. N. Senkov, A critical review of high entropy alloys and related concepts, Acta Mater. 122 (2017) 448-511. doi:10.1016/j.actamat.2016.08.081.
[4] C. M. Rost, E. Sachet, T. Borman, A. Moballegh, E. C. Dickey, D. Hou, J. L. Jones, S. Curtarolo, J. P. Maria, Entropy-stabilized oxides, Nat. Commun. 6 (2015) 1-8. doi:10.1038/ncomms9485.
[5] J. Gild, Y. Zhang, T. Harrington, S. Jiang, T. Hu, M. C. Quinn, W. M. Mellor, N. Zhou, K. Vecchio, J. Luo, High-Entropy Metal Diborides: A New Class of High-Entropy Materials and a New Type of Ultrahigh Temperature Ceramics, Sci. Rep. 6 (2016) 2-11. doi:10.1038/srep37946.
[6] P. Sarker, T. Harrington, C. Toher, C. Oses, M. Samiee, J. P. Maria, D. W. Brenner, K. S. Vecchio, S. Curtarolo, High-entropy high-hardness metal carbides discovered by entropy descriptors, Nat. Commun. 9 (2018) 1-10. doi:10.1038/s41467-018-07160-7.
[7] C. Oses, C. Toher, S. Curtarolo, High-entropy ceramics, Nat. Rev. Mater. 5 (2020) 295-309. doi:10.1038/s41578-019-0170-8.
[8] D. Liu, Y. Huang, L. Liu, L. Zhang, A novel of MSi2 high-entropy silicide: Be expected to improve mechanical properties of MoSi2, Mater. Lett. 268 (2020). doi :10.1016/j.matlet.2020.127629.
[9] J. Gild, J. Braun, K. Kaufmann, E. Marin, T. Harrington, P. Hopkins, K. Vecchio, J. Luo, A high-entropy silicide: (Mo 0.2 Nb 0.2 Ta 0.2 Ti 0.2 W 0.2)Si 2, J. Mater. (2019). doi :10.1016/j.j mat.2019.03.002.
[10] R. W. Mann, L. A. Clevenger, P. D. Agnello, F. R. White, Silicides and local interconnections for high-performance VLSI applications, IBM J. Res. Dev. 39 (1995) 403-417.
[11] O. N. Senkov, C. Zhang, A. L. Pilchak, E. J. Payton, C. Woodward, F. Zhang, CALPHAD-aided development of quaternary multi-principal element refractory alloys based on NbTiZr, J. Alloys Compd. 783 (2019) 729-742. doi:10.1016/j.jallcom.2018.12.325.
[12] D. J. M. King, S. C. Middleburgh, A. G. McGregor, M. B. Cortie, Predicting the formation and stability of single phase high-entropy alloys, Acta Mater. 104 (2016) 172-179. doi:10.1016/j.actamat.2015.11.040.
[13] F. Zhang, C. Zhang, S. L. Chen, J. Zhu, W. S. Cao, U. R. Kattner, An understanding of high entropy alloys from phase diagram calculations, Calphad Comput. Coupling Phase Diagrams Thermochem. 45 (2014) 1-10. doi:10.1016/j.calphad.2013.10.006.
[14] H. Mao, H. L. Chen, Q. Chen, TCHEAl: A Thermodynamic Database Not Limited for “High Entropy” Alloys, J. Phase Equilibria Diffus. 38 (2017) 353-368. doi:10.1007/s11669-017-0570-7.
[15] B. H. Toby, R. B. Von Dreele, GSAS-II: The genesis of a modern open-source all purpose crystallography software package, J. Appl. Crystallogr. 46 (2013) 544-549. doi:10.1107/S0021889813003531.
[16] C. A. Schneider, W. S. Rasband, K. W. Eliceiri, NIH Image to ImageJ: 25 years of image analysis, Nat. Methods. 9 (2012) 671-675. doi:10.1038/nmeth.2089.
[17] ASTM Standard E112-13, 2013, “Standard test methods for determining average grain size”, ASTM Int. (2013). doi:10.1520/E0112-13.1.4.
[18] W. J. Boettinger, J. H. Perepezko, P. S. Frankwicz, Application of ternary phase diagrams to the development of MoSi 2 -based materials, Mater. Sci. Eng. A. 155 (1992) 33-44. doi:10.1016/0921-5093(92)90310-W.
[19] K. Maex, M. Van Rossum, Properties of Metal Silicides, (1995).
[20] P. S. Frankwicz, J. H. Perepezko, Phase stability of MoSi2 in the C11b and C40 structures at high temperatures, Mater. Sci. Eng. A. 246 (1998) 199-206. doi:10.1016/s0921-5093(97)00747-8.
[21] R. Hollerweger, D. Holec, J. Paulitsch, M. Bartosik, R. Daniel, R. Rachbauer, P. Polcik, J. Keckes, C. Krywka, H. Euchner, P. H. Mayrhofer, Complementary ab initio and X-ray nanodiffraction studies of Ta205, Acta Mater. 83 (2015) 276-284. doi:10.1016/S1474-4422(10)70250-7.
[22] P. Aloke, S. Divinski, Handbook of Solid State Diffusion, Volume 2 -Diffusion Analysis in Material Applications, Elsevier, 2017. https://app.knovel.com/hotlink/toc/id:kpHSSDVDAl/handbook-solid-state/handbook-solid-state.
[23] C. L. Yaws, Yaws' Handbook of Thermodynamic Properties for Hydrocarbons and Chemicals, Knovel, 2009. https://app.knovel.com/hotlink/toc/id:kpYHTPHC09/yaws-handbook-thermodynamic/yaws-handbook-thermodynamic.
[24] A. R. Denton, N. W. Ashcroft, Vegard's law, Phys. Rev. A. 43 (1991) 3161-3164. doi:10.1002/pssb.19660180251.

### Supplementary References

[1] D. Liu, Y. Huang, L. Liu, L. Zhang, A novel of MSi2 high-entropy silicide: Be expected to improve mechanical properties of MoSi2, Mater. Lett. 268 (2020). doi :10.1016/j .matlet.2020.127629.
[2] J. Gild, J. Braun, K. Kaufmann, E. Marin, T. Harrington, P. Hopkins, K. Vecchio, J. Luo, A high-entropy silicide: (Mo 0.2 Nb 0.2 Ta 0.2 Ti 0.2 W 0.2)Si 2, J. Mater. (2019). doi:10.1016/j.jmat.2019.03.002.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions, or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

What is claimed is:

1. A method of forming a single-phase high entropy silicide material, the method comprising:
depositing at least two metal layers onto a silicon substrate to form a multilayer film; and
heat treating the multilayer film at a sufficient temperature to promote interdiffusion of the metal layer and the silicon substrate to form the single-phase high entropy silicide material.

2. The method of claim 1, wherein the depositing comprises electron beam evaporation of at least two metals onto the silicon substrate.

3. The method of claim 2, wherein the at least two metals comprise Cr, Mo, Ta, Nb, or V.

4. The method of claim 1, wherein the depositing comprises sequentially depositing the metal layers onto the silicon substrate.

5. The method of claim 3, wherein the at least two metal layers comprise, in no particular order, a first layer comprising Cr, a second layer comprising Mo, and a third layer comprising Ta.

6. The method of claim 5, wherein the Cr, Mo, and Ta are deposited onto the Si substrate in an approximately equiatomic ratio.

7. The method of claim 1, wherein the single-phase silicide material is (CrMoTa)Si₂.

8. The method of claim 2, wherein the at least two metal layers comprise, in no particular order, a first layer comprising Cr, a second layer comprising Mo, a third layer comprising Ta, a fourth layer comprising Nb, and a fifth layer comprising V.

9. The method of claim 8, wherein the Mo, Cr, Ta, Nb, and V are deposited onto the Si substrate in an approximately equiatomic ratio.

10. The method of claim 1, wherein the single-phase silicide material is (CrMoTaVNb)Si₂.

11. The method of claim 1, wherein the heat treating is conducted at 700 to 1000 degrees Celsius.

12. The method of claim 1, wherein the heat treating is conducted for 30 minutes to 90 minutes.

13. Single-phase high entropy (CrMoTa)Si₂.

14. Single-phase high entropy (CrMoTaVNb)Si₂.

15. A method of identifying single-phase high entropy silicides (HES) comprising using a CALculation of PHAse Diagrams (CALPHAD) approach to identify two candidate single-phase high entropy silicides (HES): the ternary (CrMoTa)Si₂ and the quinary (CrMoTaVNb)Si₂.

16. The method claim 15, wherein both the ternary (CrMoTa)Si₂ and the quinary (CrMoTaVNb)Si₂ HES films form a single phase with a C40 hexagonal crystal structure.

17. The method of claim 15, further comprising the step of synthesizing both candidate single-phase HES via electron beam evaporation followed by heat treatment in vacuum, to facilitate a solid-state reaction and formation of a single phase.

18. A thin film high entropy silicide material fabricated using the method of claim 15.
